(19) United States
(12) Patent Application Publication
(10) Pub. No.: US 2016/0046239 A1
(43) Pub. Date: Feb. 18, 2016

(54) REARVIEW MIRROR WITH SELECTIVE REFELCTION AND METHOD OF MANUFACTURE

(71) Applicant: Muth Mirror Systems, LLC, Sheboyan, WI (US)

(72) Inventors: Daniel Mathieu, Sheboygan Falls, WI (US); Timothy Severn, Sheboygan, WI (US); Matthew Gagner, Sheboygan, WI (US); Seth Van Gheem, Sheboygan, WI (US)

(21) Appl. No.: 14/826,675

(22) Filed: Aug. 14, 2015

Related U.S. Application Data
(60) Provisional application No. 62/037,837, filed on Aug. 15, 2014.

(51) Int. Cl. B60R 1/12; C23C 14/04; F21S 8/10; B60Q 1/26; B60Q 1/34

(52) U.S. Cl. CPC B60R 1/1207; B60Q 1/2665; B60Q 1/34; F21S 48/234; F21S 48/238; C23C 14/042; B60R 2001/1215

(57) ABSTRACT

An optic assembly for an automotive rearview mirror including a reflector having facets for managing light from a light source in the optic assembly and for lighting an illuminated feature in the rearview mirror. The reflector is selectively reflective, such that not all surface areas within the reflector are reflective. A method for manufacturing the reflector includes a process for selectively metallizing the reflector.

### CROSS REFERENCE TO RELATED APPLICATIONS

This application claims the benefit of U.S. Provisional Patent Application Ser. No. 62/037,837, filed Aug. 15, 2014, the disclosure of which is herby incorporated by reference in its entirety for all purposes.

### FIELD OF THE INVENTION

The present invention relates generally to optic assemblies for automotive rearview mirrors. More particularly, the present invention relates to an improved optic assembly and method of manufacturing the assembly using selective metallization.

### BACKGROUND

An automotive rearview mirror needs to provide certain visual information to a driver, while at the same time, not causing a disturbance to the driver or passengers, or to those in other vehicles travelling nearby. Some examples of existing automotive rearview mirrors and optic assemblies used for illuminating lighted features are shown in U.S. Pat. No. 8,708,536, which is incorporated herein by reference for all purposes. It is desirable for optic assemblies used in rearview mirrors to be as light and as small as possible, and to use as few LEDs or light sources as necessary. To reduce the number of light sources used, light rays from a light source in the optic assembly are reflected and directed by a reflector or reflectors in the optic assembly to direct light through apertures to illuminate the lighted features or manage light as otherwise desired. Reflectors used in the optic assembly can be angled, flat, stepped, curved or otherwise shaped to direct and orient light emitted from the light source. These angles, flats, curves or other shapes that form the topography of the reflective surface are referred to as “facets” by the inventors.

As automobile designers and manufacturers continue to desire smaller and thinner optic assemblies, a need exists for better light reflection control in optic assemblies used with rearview mirrors and other mirror assemblies. Small, thin reflectors are desirable because they offer lower weight, and a smaller form factor, thereby reducing the overall size and weight of the automotive mirror. With thin reflectors with shallow facets, it becomes more difficult to control the light in the optic assembly, and thus the amount of “stray light,” that is, light emitted in undesired or less than ideal directions. Manufactures also need increasingly efficient ways to manufacture complex and small optic assemblies to meet the specifications of automobile designer and manufacturers.

By using selective reflection in an optic assembly in an automotive rearview mirror, the light control challenges inherent in thin reflectors can be reduced. This enables more light control to be built directly into the reflector, such that additional light control elements, such as light control screens, are no longer needed to control stray light. Selective reflection is applied to the reflector in a selective metallization process using a mask to cover portions of the reflector that should not be metallized, and allowing metallization of the portions of the reflector that should be metallized. The process is efficient and cost effective and allows very effective improvement of light control to meet the desires of automobile designers and manufacturers for smaller, thinner, optic assemblies.

### SUMMARY

An automotive rearview mirror assembly includes a housing, a mirror mounted within the housing, an optic assembly mounted behind the mirror for lighting an illuminated feature, the optic assembly including a light source within the assembly, and a reflector, the reflector having an interior surface comprising a plurality of facets for managing the direction of light, and a reflective layer is selectively applied to the interior surface of the reflector.

An optic assembly for lighting an illuminated feature in an automotive rearview mirror assembly includes a reflector, the reflector having an interior surface, a light source emitting light into the interior surface of the reflector, the interior surface of the reflector including means for managing light rays emitted into the reflector to minimize stray light, and wherein the interior surface is selectively reflective to provide desired light control in dim zones and bright zones for viewing the illuminated feature.

A method of manufacturing an optic assembly for an automotive rearview mirror assembly including a reflector with a plurality of facets, the method including the steps of identifying a light source and reflector shape to provide desired luminescence for an illuminated feature in an automotive rearview mirror assembly, identify the facets of the reflector to apply a reflective layer to provide the desired luminescence of the illuminated feature in dim zones and in bright zones, prepare a mask assembly to selectively cover facets and expose other facets that will receive the reflective layer, apply a reflective layer using a metallizing process, and wherein the method results in metallized areas and non-metallized areas of the reflector to provide desired luminescence without the use of a light control screen or other light control elements.

It will be understood by those skilled in the art that one or more aspects of this invention can meet certain objectives, while one or more other aspects can lead to certain other objectives. Other objects, features, benefits and advantages of the present invention will be apparent in this summary and descriptions of the disclosed embodiments, and will be readily apparent to those skilled in the art. Such objects, features, benefits and advantages will be apparent from the above as taken in conjunction with the accompanying figures and all reasonable inferences to be drawn therefrom.

### BRIEF DESCRIPTION OF THE DRAWINGS

FIG. 1 is an environmental view of an automotive rearview mirror assembly, which uses an optic assembly to illuminate a lighted turn signal feature.

FIG. 2 is an exploded isometric view of the automotive rearview mirror assembly in FIG. 1 showing the most basic components of an optic assembly in accordance with the present invention.

FIG. 3 is an environmental view of an automotive rearview mirror assembly, which uses an optic assembly to illuminate a lighted blind spot detection display (“BSDD”) feature.

FIG. 4 is an exploded isometric view of the automotive rearview mirror assembly in FIG. 3 showing the most basic components of an optic assembly in accordance with the present invention.

FIG. 5 is a schematic illustrating the different zones of particular concern to manage stray light and to meet luminescence requirements for a lighted turn signal feature in an automotive rearview mirror.

FIG. 6 is a schematic illustrating the different zones of particular concern to manage stray light and to meet luminescence requirements for a lighted BSDD feature.

FIGS. 7a, 7b, and 7c illustrate selective reflection as accomplished by selective metallization in a series of views of a reflector for an optic assembly for a lighted BSDD feature. FIG. 7a is an isometric view of the position of the reflector from the perspective of the driver's view. FIG. 7b is a plan view of the same reflector, showing how the reflector would be positioned when viewed straight on. FIG. 7c is an isometric view of the position of the same reflector from the perspective of a viewer in a vehicle on an adjacent lane on a road.

FIGS. 8a, 8b, and 8c illustrate selective reflection as accomplished by selective metallization in a series of views of an optic assembly for a lighted turn signal feature in the left hand side rearview mirror assembly on an automobile. FIG. 8a is an isometric view of the optic assembly showing the position it would be viewed from the perspective of the driver's view. FIG. 8b is a plan view of the same optic assembly, showing how it would appear when viewed straight on. FIG. 8c is an isometric view of the same optic assembly from the position of the perspective of a viewer in a vehicle on an adjacent lane on a road.

FIG. 9 is an isometric close-up view of the optic assembly in FIG. 8.

FIG. 10 is an exploded isometric view of the reflector and the mask used to selectively metallize the optic assembly in FIG. 8.

FIG. 11a is an isometric view of an embodiment of a mask for use with an injection molded reflector. FIG. 11b shows the mask on the reflectors during production and for use in a selective metallization process.

FIGS. 12a, 12b, and 12c are a series of illustrations showing the benefits of selective reflection and selective metallization in an optic assembly. FIG. 12a shows the reflector of an optic assembly in which there is no attenuation and some stray light undesirably escapes to the left. FIG. 12b shows the same reflector as in FIG. 12a, with the addition of a light control film to manage light to reduce light escaping in undesirable directions. FIG. 12c shows a reflector for the same lighted feature, but employing selective reflection by way of selective metallization to manage light, and in which the light control film is not necessary.

### DETAILED DESCRIPTION

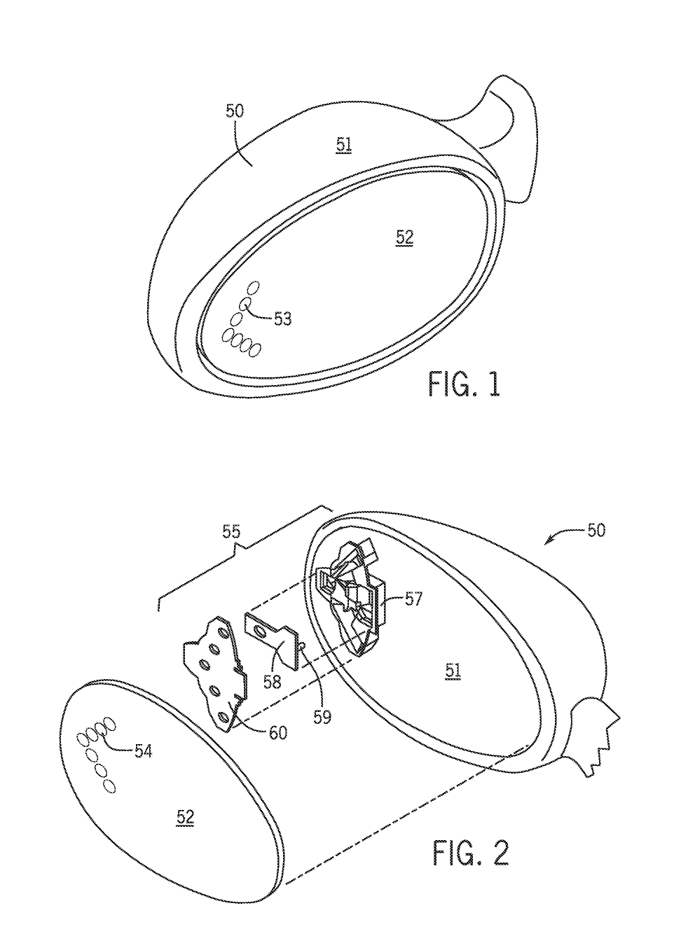

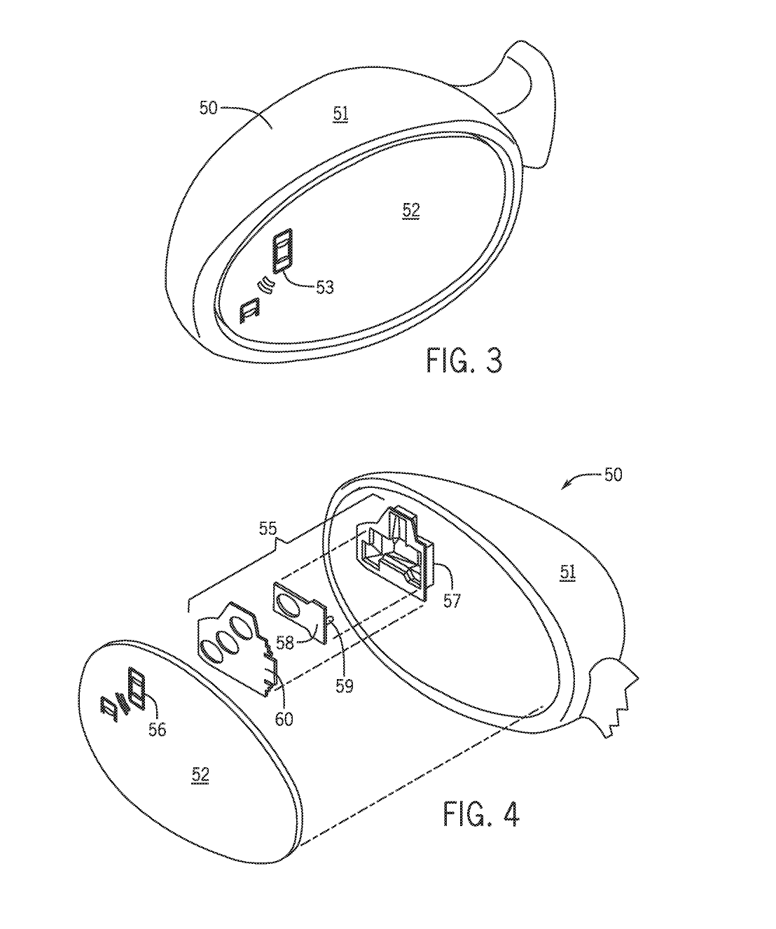

The present invention will be particularly useful in the context of optic assemblies used in rearview mirrors in the automotive industry, but will also be useful in other contexts for other assemblies with illuminated features, for example in industrial, construction, farm vehicles, residential and commercial lighting, and in other machines or equipment. FIG. 1 shows one example of an automotive rearview mirror assembly 50, including housing 51 and mirror 52, the mirror having an illuminated feature 53, namely a lighted turn signal feature employing an optic assembly in accordance with the present invention. FIG. 2 shows the basic components of the optic assembly 55 used to illuminate the turn signal feature 54 of the optic assembly in FIG. 1. Optic assembly 55 includes a reflector 57, circuit board 58 with a light source 59, and cover 60. A typical light source will comprise one or more LEDs. Another example of an automotive rearview mirror assembly 50 is shown in FIG. 3, but the illuminated feature 53 shown in this drawing is a blind spot detection display (“BSDD”) 56. FIG. 4 similarly shows the basic components of the optic assembly 55 for the BSSD feature. Illuminated features 53 in accordance with the invention will include a variety of different features, not just the turn signal 54 and BSDD 56 features as illustrated in this application. Other types of illuminated features 53 may include a parking assist feature, as well as other warning signals and visual indicators.

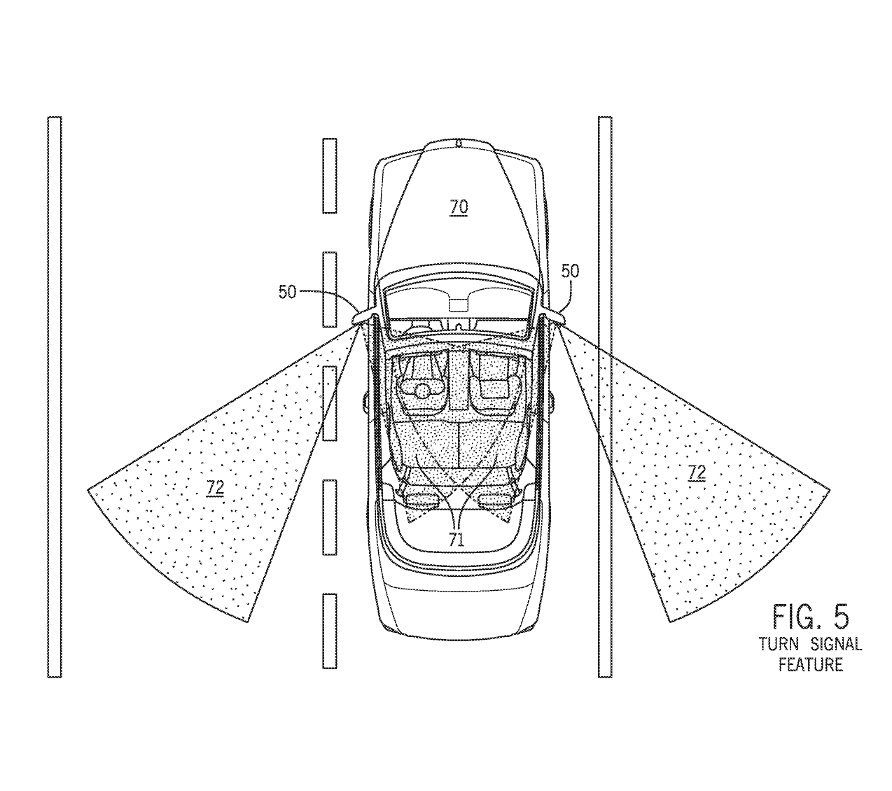

As noted above, automotive rearview mirrors must provide certain visual information to a driver, while at the same time, not causing a disturbance to the driver or passengers, or to those in other vehicles travelling nearby. FIGS. 5 and 6 are useful to explain the type of luminescence requirements and other concerns that may be considered in designing optic assemblies 55 and in designing certain types of illuminated features 53.

FIG. 5 illustrates these issues in connection with a turn signal illuminated feature. As seen in the drawing, automobile 70 includes rearview mirror assemblies 50. FIG. 5 shows that in certain maximum luminescence zones 71 that particularly impact the driver and passengers of a vehicle, the illuminated feature and automotive rearview mirror assembly needs to meet certain maximum luminescence requirements to ensure that the illuminated feature—in this case a turn signal feature—does not usually impair or distract the driver and passengers of the car. Likewise, in certain minimum luminescence zones 72, the illuminated feature needs to meet certain minimum luminescence requirements to ensure visibility to other drivers, including drivers in the adjacent lane.

FIG. 6 illustrates the type of luminescence requirements concerns that may be at issue with a BSDD feature. With an illuminated BSDD feature, there will be bright zones 73 in which the illuminated feature should meet certain minimum luminescence requirements to ensure that the driver can see the feature and to ensure that the feature is useful to the driver. Likewise, there will also be dim zones 74 in a BSDD application, where in these zones, the illuminated feature should be relatively dim so as to not distract or impair the visibility of drivers of other vehicles.

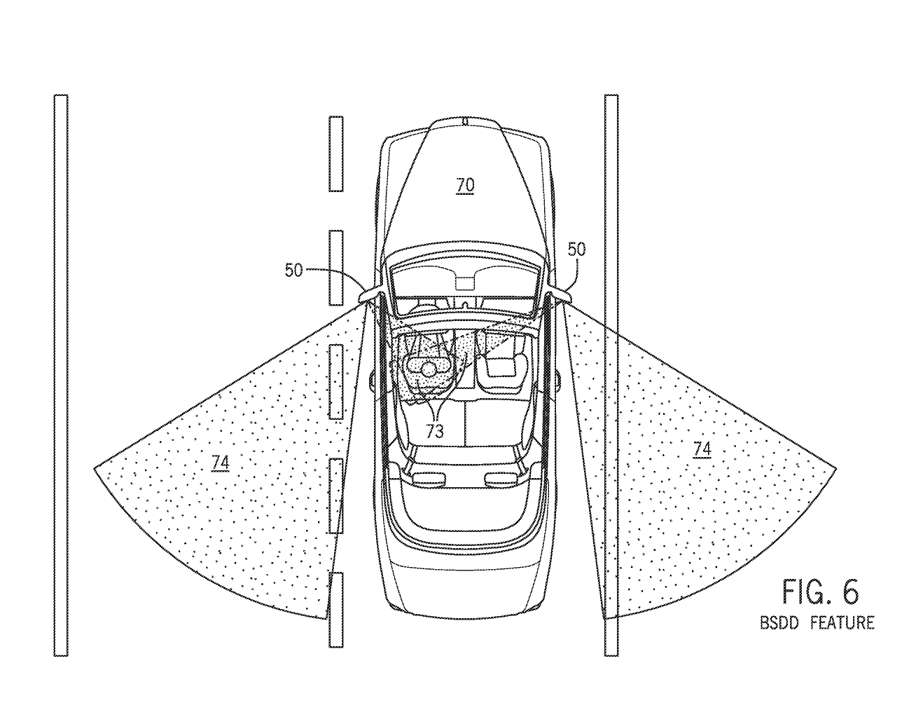

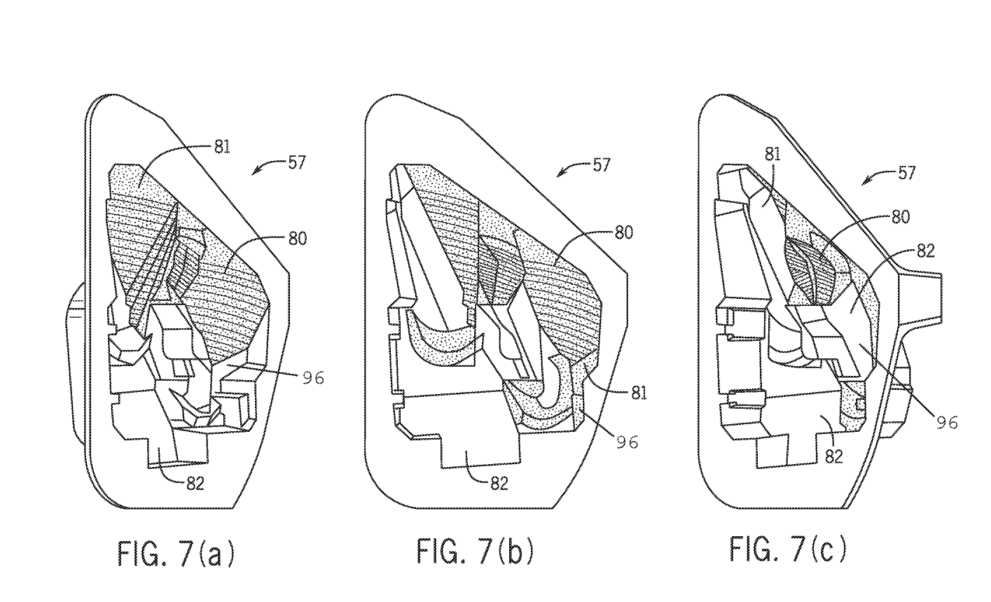

The inventors have invented improved optic assemblies that address and solve the challenges described above by using an optic assembly with selective reflection, manufactured using a selective metallization process. FIGS. 7a, 7b, and 7c illustrate selective reflection as accomplished by selective metallization in a series of views of the reflector for an optic assembly for a lighted BSDD feature. FIG. 7a is an isometric view of the reflector 57 from the perspective of the driver's view. FIG. 7b is a plan view of the same reflector 57, showing how the reflector would appear when viewed straight on. FIG. 7c is an isometric view of the same reflector 57 from the perspective of a viewer in a vehicle on an adjacent lane on a road. As can be seen in the drawings, the interior surface 96 of the reflector contains facets 80 for directing and managing light from the light source of the optic assembly. Additional information regarding facets is described in U.S. Pat. No. 8,708,536. Some areas of the reflector surface are metallized areas 81, meaning that a reflective metal material is applied to the reflector in these areas. Other areas of the reflector surface are non-metallized areas 82, in which the reflective metal is not applied to the reflector. If the reflector is made from a dark material, the non-metallized areas remain dark and are minimally reflective. This selective reflection provides an improved way to manage light within the optic assembly.

The metallization process used may be any suitable metallization process, for example, a vacuum deposition process. Vacuum deposition is a family of processes used to deposit layers of material on a solid surface. These processes operate at pressures well below atmospheric pressure (vacuum) and the deposited layers can range from a thickness of one atom up to several millimeters. Thermal evaporation is a common method of thin-film deposition. The source material is evaporated in a vacuum, the vacuum allows vapor particles to travel directly to the target object (substrate), where they condense back to a solid state. One example of a vacuum deposition process may include: a polycarbonate substrate (without a base coat); followed by aluminum vacuum metallization; further followed by an in-chamber top coat. As another example, the process could include: an ABS substrate; an enamel base coat; aluminum vacuum metallization; followed by an enamel top coat. Other metallization processes may be used as well within the scope of the invention.

Selective metallization according to this disclosure is especially beneficial when it is applied to a thin reflector with shallow facets. Such thin reflectors are beneficial, for they offer lower weight, and a smaller form factor, thereby reducing the overall size and weight of the automotive mirror. With thin reflectors with shallow facets, it becomes more difficult to control the direction of any reflected light and manage stray light, but with the selective metallization process of this disclosure, the amount of stray light is significantly reduced. This has been found to be especially true and selective metallization especially effective with thin reflectors of less than 10 millimeters in depth, and even more so with reflectors of less than 7 millimeters in depth.

Further, by using selective reflection in an automotive rearview mirror reflector, the light control problems inherent in thin reflectors can be reduced, without the need to resort to other light control elements, such as light control screens, which increase the depth of the reflector package. Since these additional elements are no longer needed, this reduces the number of parts and the overall reflector depth required to obtain the desired light pattern. Fewer parts mean lower cost, and this provides a commercial advantage. And without the need to add a light control screen between a reflector and the outer transparent layer, the reflector may even be sealed directly to the transparent layer. An additional benefit of selective reflection is that optic assemblies or reflectors employing selective reflection require less plastic parts or multi-injection, and perhaps less or simpler faceting on the interior surface of the reflector.

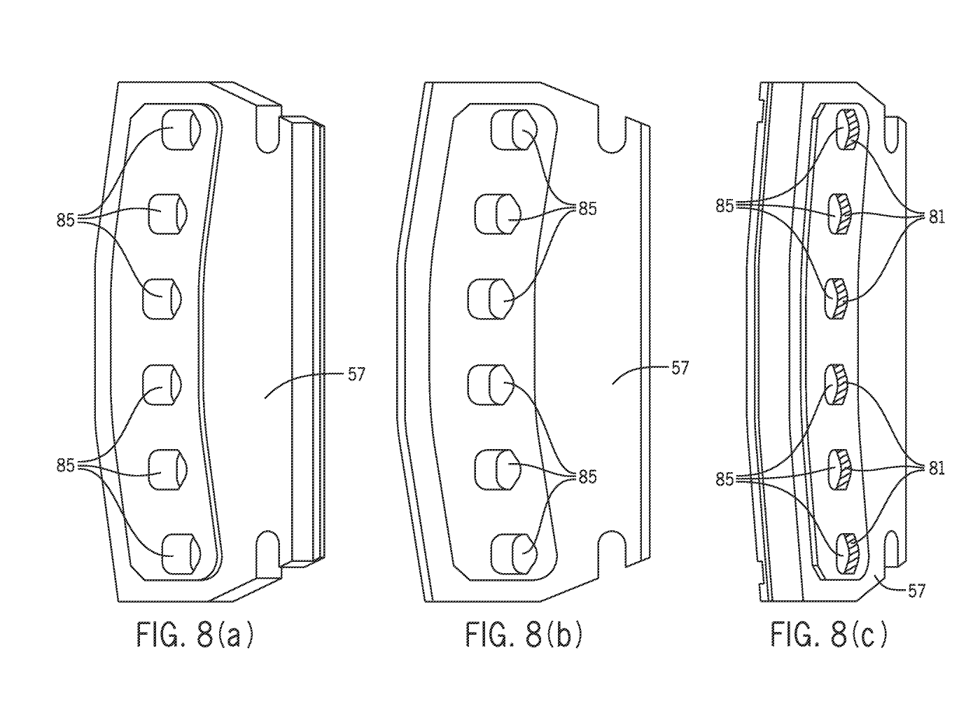

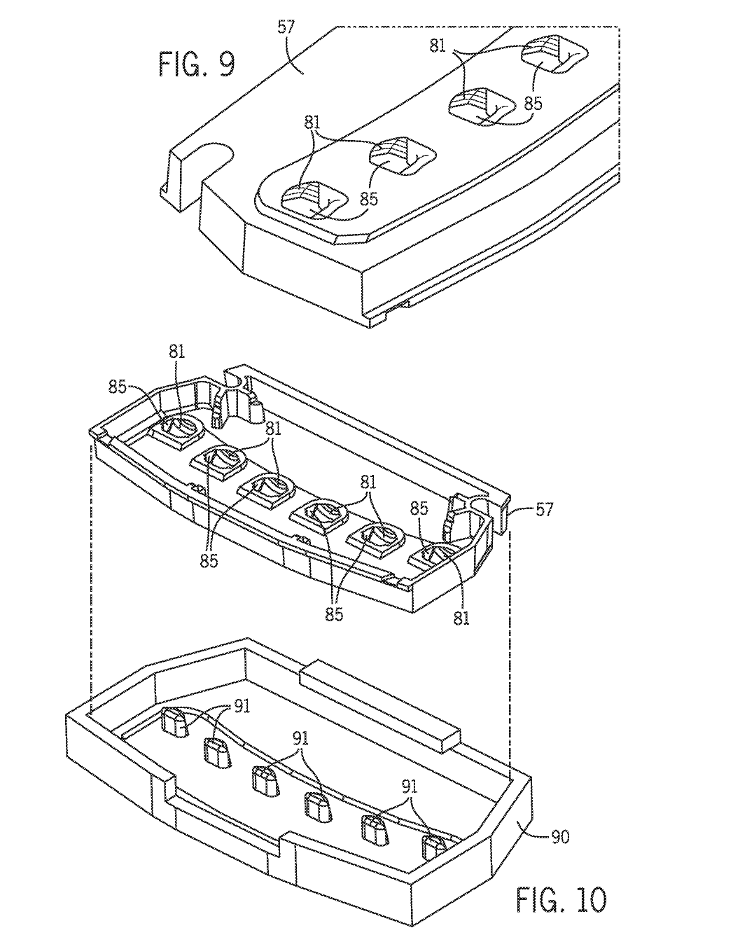

Another example of selective reflection in a different illuminated feature is shown in FIGS. 8a, 8b, and 8c, which provide a series of views of a reflector 57 for a lighted turn signal feature in the left hand side rearview mirror assembly on an automobile. FIG. 8a is an isometric view of the reflector 57 as it would be positioned from the perspective of the driver's view. FIG. 8b is a plan view of the same reflector 57, showing how it would be positioned when viewed straight on. FIG. 8c is an isometric view of the same reflector 57 from the perspective of a viewer in a vehicle on an adjacent lane on a road. As seen in the drawings, the reflector 57 for the turn signal feature includes apertures 85 for light to exit the optic assembly and illuminate the turn signal feature. Selective metallization is employed to metalize and make reflective only certain surfaces of the reflector 57, so that when the turn signal feature is viewed by the driver or straight on (as in FIGS. 8a and 8b), the turn signal is only minimally visible to the driver so as to not be distracting or disruptive to the driver. But, the metallization is applied such that when the turn signal feature is viewed by drivers in adjacent lanes, the illuminated feature will be brighter and readily visible to those drivers. This illustrated in FIG. 8c, which is the only drawing in the series—and the only illustrated position of the reflector—in which the metallization is visible. FIG. 9 is an isometric close-up view of the reflector 57 in FIG. 8 showing a closer view of the metallized areas 81 of the apertures 85 in the reflector 57.

To accomplish this selective reflection, a mask 90 is used during manufacturing of the optic assemblies to selectively metalize the reflector or other components of the optic assembly, resulting in metallized areas and non-metallized areas. As an example of a mask 90 can be seen in FIG. 10, which is an exploded isometric view of the reflector 57 and the mask 90 used to make the optic in FIG. 8. As shown in FIG. 10, mask 90 has protrusions 91 that, when the mask is mated with reflector 57 during manufacturing, cause the protrusions 91 to cover portions of the reflector surfaces that form the apertures 85, leaving other portions uncovered. During the metallization process during manufacturing, those portions become metallized areas 81.

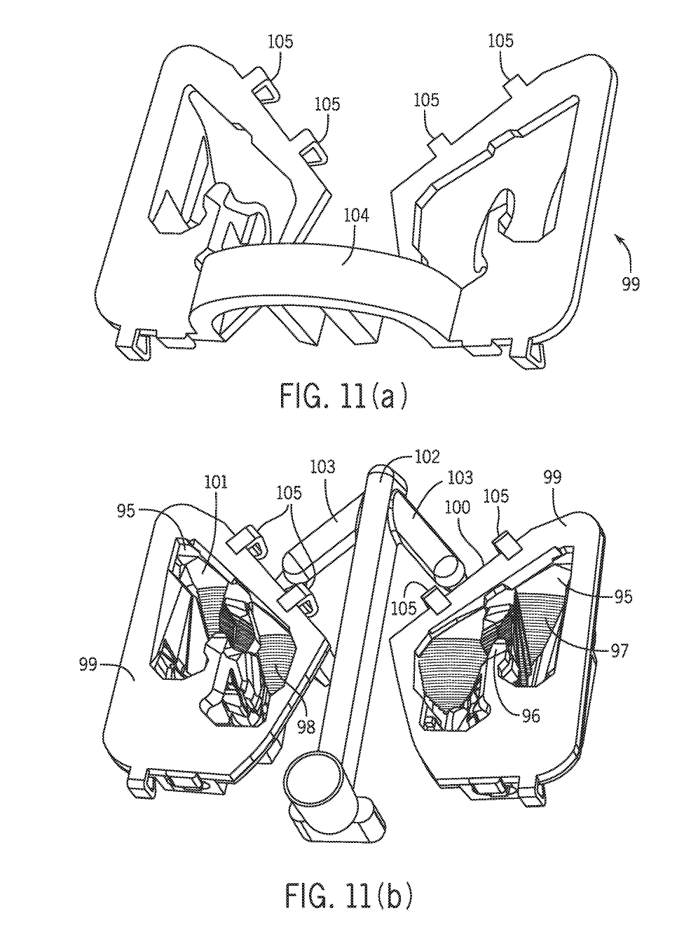

FIGS. 11a and 11b illustrate another embodiment of mask 99 and also illustrate a method of manufacturing a reflector 95 for a BSDD illuminated feature, the reflector 95 including an interior surface 96 with a plurality of facets 97, and a layer of reflective material 98 applied to less than all of the surface areas on the interior surface 96. More particularly, a method of selectively metallizing two reflectors 95 at once is shown. A mask 99 is created that selectively covers certain covered surface areas 100 of each of the reflectors 95, the covered surface areas being those that should not be metallized. Mask 99 is shown in FIG. 11a. After placing the mask 99 over each reflector 95, the exposed surface areas 101 are then metallized, such as by using vacuum metallization or physical vapor deposition, but any means of selectively placing a reflective coating or material on the selected base surface areas is within the scope of this disclosure. For example, in other embodiments (not shown), the reflective layer 95 can be applied to a respective selected reflector base surface area by an adhesive.

As shown in FIG. 11b, a pair of reflectors 95 is injection molded, with each of the two reflectors 95 being supported on a runner 102 by extensions 103 from the runner. During manufacturing, and in particular, during the application of the reflective material 98 to interior surface 96 (i.e. during metallization), mask 99 is fitted over reflectors 95. The respective individual mask for each reflector base is secured to the other mask by a connecting bridge 104. And each mask 99 is releasably held on its respective reflector 95 by a plurality of clips 105 that extend from spaced apart locations on the mask periphery and then around the reflector. The clips 105 are flexible, and thus can be bent so as to either secure the mask to the reflector 95, or to release the mask from the reflector 95 after the reflective material 98 is applied to the selected exposed surface areas 101.

In one embodiment, the reflector 95 is formed by injection molding a non-reflective material, such as a black plastic, such as ABS (Acrylonitrile butadiene styrene) or PC (polycarbonate) material. But in other embodiments, any means of forming the base is within the scope of this disclosure. For example, other materials could be used, such as wood or metal, and other methods of creating the desired surface areas, such as by machining or by carving, are within the scope of this disclosure. In the illustrated embodiments, the various surface areas constitute facets which extend at various angles relative to a longitudinal axis of the reflector base, thereby creating various possible light reflection directions. In order to permit light reflection in some but not all directions, only selected surface areas have a layer of applied reflective material.

In a BSDD application, for example, selective metallization is deployed to achieve a high level of display luminance and acceptable appearance including uniformity in the direction of the driver's viewing angle (for example 40°-75°) while significantly attenuating the display luminance at the adjacent lane angles (for example 120° or higher). The selective metallization works in conjunction with the reflector being injection molded with a non-reflective material; typically a black thermoplastic like ABS or PC.

The process of selective metallization involves analysis of the optic capabilities and reflective capabilities of a given reflector and light source. Light source and reflector shape are identified as well as the desired luminescence characteristics for the particular application and lighted feature. Covered surface areas and exposed surface areas of the reflector must be identified as those will become the metallized and non-metallized areas of the reflector. A mask may be designed and used during the metallization process for the reflector. The materials for a metalized layer are selected and the metallized layer is applied to the reflector, thereby metallizing some areas of the reflector, but not others.

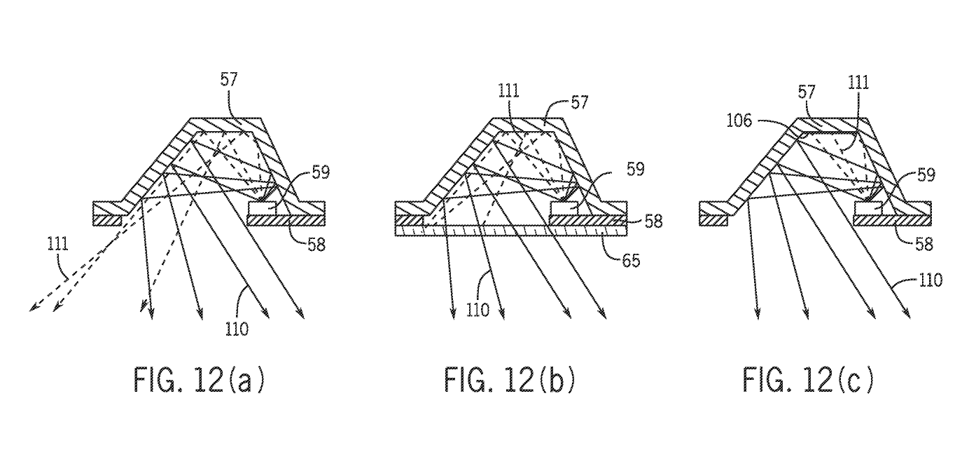

FIGS. 12a, 12b, and 12c are a series of illustrations showing the benefits of selective reflection and selective metallization in an optic assembly. FIG. 12a shows the reflector 57 of an optic assembly in which there is no attenuation, or at least not a significant manipulation or management of the direction of light within the assembly, and creates significant amounts of stray light. In FIG. 12a, reflector 57 is shown with reference to light source 59 on circuit board 58. Light rays traveling in a desirable direction 110 are noted in solid lines, and light rays traveling in an undesirable direction 111, i.e. stray light, is shown in broken lines.

FIG. 12b shows the same reflector 57 as in FIG. 12a, with the addition of a light control film 65 to improve light management and efficiency, which reduces the light escaping in undesirable directions 111.

FIG. 12c shows the improvement in accordance with the present invention, including a reflector 57 for the same lighted feature, but employing selective reflection and selective metallization to manage light, and in which the light control film is not necessary. A selectively metallized surface is denoted with reference number 106 in FIG. 12c to illustrate the concept.

Although the invention has been herein described in what is perceived to be the most practical and preferred embodiments, it is to be understood that the invention is not intended to be limited to the specific embodiments set forth above. Rather, it is recognized that modifications may be made by one of skill in the art of the invention without departing from the spirit or intent of the invention and, therefore, the invention is to be taken as including all reasonable equivalents to the subject matter of the appended claims and the description of the invention herein.

What is claimed is:

1. An automotive rearview mirror assembly comprising:
a housing;
a mirror mounted within the housing; and
an optic assembly mounted behind the mirror for lighting an illuminated feature, the optic assembly comprising:
a light source within the assembly; and
a reflector, the reflector having an interior surface comprising a plurality of facets for managing the direction of light; and
a reflective layer selectively applied to the interior surface of the reflector.

2. The automotive rearview mirror assembly of claim 1, wherein the reflective layer selectively applied to the interior surface of the reflector comprises metallized areas and non-metallized areas.

3. The automotive rearview mirror assembly of claim 2 wherein the reflective layer is applied by selective metallization.

4. The automotive rearview mirror assembly of claim 1 wherein the illuminated feature is a lighted turn signal.

5. The automotive rearview mirror assembly of claim 1 wherein the illuminated feature is a blind spot detection display.

6. The automotive rearview mirror assembly of claim 1 wherein the reflector is less than 10 mm deep.

7. The automotive rearview mirror assembly of claim 1 wherein the reflector is less than 7 mm deep.

8. An optic assembly for lighting an illuminated feature in an automotive rearview mirror assembly comprising:
a reflector, the reflector having an interior surface;
a light source emitting light into the interior surface of the reflector;
the interior surface of the reflector including means for managing light rays emitted into the reflector to minimize stray light; and
wherein the interior surface is selectively reflective to provide desired light control, resulting in desired dim zones and bright zones for viewing the illuminated feature.

9. The optic assembly of claim 8, wherein the interior surface includes a reflective layer selectively applied and comprising metallized areas and non-metallized areas.

10. The optic assembly of claim 9 wherein the reflective layer is applied by selective metallization.

11. The optic assembly of claim 8 wherein the illuminated feature is a lighted turn signal.

12. The optic assembly of claim 8 wherein the illuminated feature is a blind spot detection display.

13. The optic assembly of claim 8 wherein the reflector is less than 10 mm deep.

14. The optic assembly of claim 8 wherein the reflector is less than 7 mm deep.

15. The optic assembly of claim 12 wherein the reflector is less than 7 mm deep.

16. A method of manufacturing an optic assembly for an automotive rearview mirror assembly including a reflector with a plurality of facets, the method comprising the steps of:
identifying a light source and reflector shape to provide desired luminescence for an illuminated feature in an automotive rearview mirror assembly;
identify the facets of the reflector to apply a reflective layer to provide the desired luminescence of the illuminated feature in dim zones and in bright zones;
prepare a mask assembly to selectively cover facets and expose other facets that will receive the reflective layer;
apply a reflective layer using a metallizing process;
wherein the method results in metallized areas and non-metallized areas of the reflector to provide desired luminescence without the use of other light control elements.

17. The method of claim 16 further comprising providing a pair of reflectors supported on a runner to receive the reflective layer.

18. The method of claim 17 wherein the mask is secured to the pair of reflectors.

19. The method of claim 16 wherein the reflector is less than 10 mm deep.

20. The method of claim 16 wherein the reflector is less than 7 mm deep.
